(19) United States
(12) Patent Application Publication
(10) Pub. No.: US 2026/0354091 A1
(43) Pub. Date: Nov. 5, 2026

(54) FLUID MEASUREMENT METHOD IN SEMICONDUCTOR SYSTEM ENVIRONMENT

(71) Applicant: Applied Materials, Inc., Santa Clara, CA (US)

(72) Inventors: Alex HUNG, Singapore (SG); Patrick CHUAN, Hsinchu (TW); Chung Yi CHANG, Hsinchu (TW); Neng Fa LIN, Hsinchu (TW); Kim Seong SIM, Singapore (SG); Ebony CHIANG, Hsinchu (TW); Johnny HSIEH, Hsinchu (TW); Justin H. WONG, Pleasanton, CA (US)

(21) Appl. No.: 19/198,352

(22) Filed: May 5, 2025

(51) Int. Cl. H10P 72/00; H10P 52/00

(52) U.S. Cl. CPC H10P 72/0604; H10P 52/00; H10P 72/0408; H10P 72/0472

(57) ABSTRACT

A processing system is disclosed herein. The processing system includes a factory interface module, a cleaner module having a drying module, a polishing module coupled to the cleaner module, a fluid flow path defined through the factory interface module, the cleaner module and the polishing module, a first sensor disposed along the fluid flow path, a second sensor disposed along the fluid flow path, and a controller in communication with the first and second sensors. The factory interface module includes a substrate receiving aperture The controller is configured to determine if a characteristic of the fluid flow path is outside of a threshold during a chemical-mechanical polishing operation.

### BACKGROUND

### Field

Embodiments described herein generally relate to equipment used in the manufacturing of electronic devices, and more particularly, to a substrate processing system with airflow monitoring capabilities.

### Description of the Related Art

Substrate processing units may perform chemical mechanical polishing (CMP), which is commonly used in the manufacturing of high-density integrated circuits to planarize or polish a layer of material deposited on a substrate. In a typical CMP process, a substrate is retained in a carrier head that presses the backside of the substrate towards a rotating polishing pad in the presence of a polishing fluid. Material is removed across the material layer surface of the substrate in contact with the polishing pad through a combination of chemical and mechanical activity. The chemical and mechanical activity can produce contaminants in the form of dust capable of floating within the cleaning system and adhering to cleaned substrates.

Therefore, a solution is needed to reduce the presence of dust and prevent contamination of substrates within a cleaning system.

### SUMMARY

Embodiments of the present disclosure generally relate to substrate processing systems. In one embodiment, a processing system is disclosed herein. The processing system includes a factory interface module, a cleaner module having a brush box cleaner, a polishing module having a polishing pad, a fluid flow path defined through the factory interface module, the cleaner module and the polishing module, a sensor disposed along the fluid flow path, and a controller in communication with the sensor. The factory interface module includes a substrate receiving aperture. The controller is configured to determine if a characteristic of the fluid flow path is outside of a threshold during a chemical-mechanical polishing operation.

In another embodiment, a processing system is disclosed herein. The processing system includes a tool, an airflow monitoring kit, and a controller. The tool includes a factory interface module includes a substrate receiving aperture, a cleaner module includes a brush box cleaners, a polishing module includes a polishing pad, and a fluid flow path defined through the factory interface module, the cleaner module and the polishing module. The airflow monitoring kit includes one or more flow devices in communication with the fluid flow path, and one or more sensors disposed along the fluid flow path. The controller configured to detect a characteristic of the fluid flow path with the one or more sensors and actuate one or more of the one or more flow devices if the characteristic is outside of a threshold.

In another embodiment, a method is disclosed herein. The method includes detecting a characteristic of a fluid flow path through a processing system with one or more sensors during a chemical-mechanical polishing operation. The method further includes determining if the characteristic is within a threshold, actuating a flow device if the characteristic is outside of the threshold, detecting an adjusted characteristic of the fluid flow path after actuating the flow device during the chemical-mechanical polishing operation, and determining if the adjusted characteristic is within the threshold.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a top view of a chemical mechanical polishing (CMP) processing system according to one or more embodiments.

FIG. 2 is a top plan view of a CMP processing system according to one or more embodiments.

FIG. 3 is a schematic block diagram of a method of maintaining a fluid flow in a chemical mechanical polishing system according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to equipment used in the manufacturing of electronic devices, and more particularly, to cleaning systems, tools, and modules used to clean the surface of a substrate following chemical mechanical polishing of the substrate in a semiconductor device manufacturing process. Maintaining a clean environment within the systems, tools, and modules is in part achieved by maintaining air flows from an inlet to an exhaust and minimizing potential regions air can become stagnant or create a swirling effect. Substrates may release contaminants into the environment that may settle on a surface if airflows become stagnant, or contaminants may be kicked up and onto a cleaned substrate if sudden changes in airflow create a swirling effect. As described below, monitoring and controlling a fluid flow path through systems, tools, and modules enables a reduction in contamination of substrates during a cleaning process.

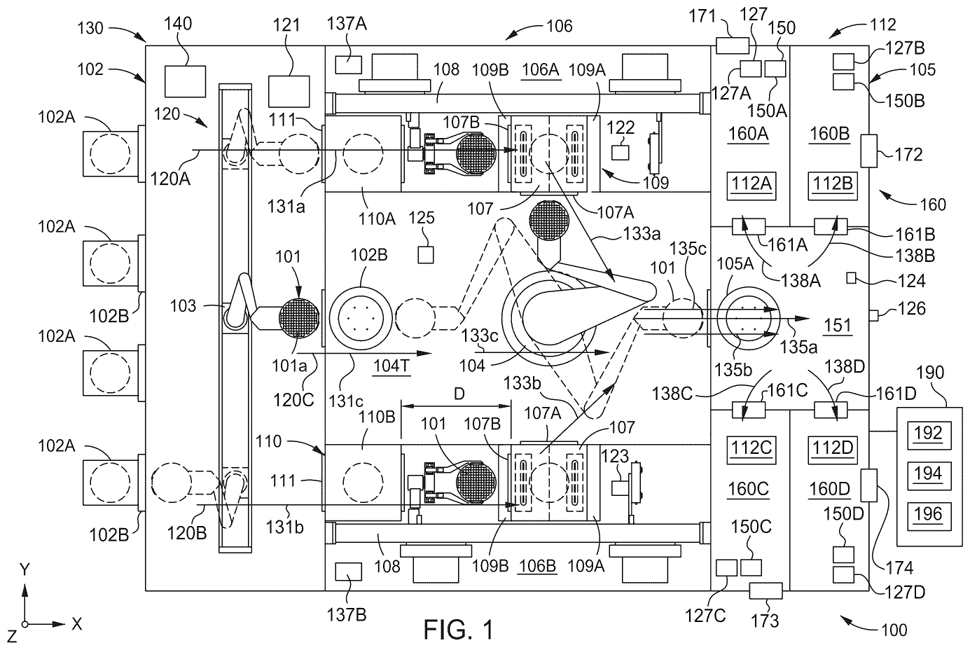

FIG. 1 is a top view of a CMP processing system 100 according to one or more embodiments. While the disclosure provided herein primarily discusses various embodiments that can be used in conjunction with a CMP device, such as a polishing module 105, this configuration is not intended to be limiting as to the scope of the disclosure provided herein.

In the figures, certain parts of the housing and certain other internal and external components are omitted to more clearly show aspects of the CMP processing system 100. Here, the CMP processing system 100 is connected to a factory interface module 102. The factory interface module 102 may include one or more loading stations 102A. The loading stations 102A are coupled to the factory interface module 102 at respective substrate receiving apertures 102B. The loading stations 102A may include, for example, front opening unified pods (FOUPs) or cassettes. Each loading station 102A may include one or more substrates 101 for CMP processing in the CMP processing system 100.

The CMP processing system 100 includes a first substrate handler 103 of the factory interface module 102, the polishing module 105, and a cleaner module 106. The cleaner module 106 includes a second substrate handler 104. The first substrate handler 103 is positioned to transfer a substrate 101 to and from one or more of the loading stations 102A. The first substrate handler 103 transfers the substrate to and from the loading station 102A with a processing surface 101a facing up.

The second substrate handler 104 may be, for example, a cleaner wet robot. The second substrate handler 104 is positioned to transfer a substrate 101 to and from the polishing module 105. For example, the second substrate handler 104 receives a substrate 101 from the first substrate handler 103 and then transfers the substrate 101 to a transfer station 105A within the polishing system 100. As another example, the second substrate handler 104 retrieves the substrate 101 from the transfer station 105A within the polishing module 105 and then transfers the substrate 101 to a horizontal pre-cleaning (HPC) module 107 in the cleaner module 106.

The polishing module 105 includes one or more polishing assemblies 112 that are used to polish a substrate 101 received from the second substrate handler 104. Each of the one or more polishing assemblies 112 includes a polishing head (not shown), configured to urge the substrate 101 against a polishing pad (not shown). Residual abrasive particles and/or liquids such as acidic or basic chemicals may remain on the substrate 101 after undergoing CMP processing in the polishing module 105. Accordingly, the cleaner module 106 is positioned between the polishing module 105 and the factory interface module 102 in order to clean the substrate 101 prior to returning the substrate 101 to the loading station 102A.

The polishing module 105 includes a transfer region 151, one or more exhausts 150, and one or more polisher sensors 127. The transfer region 151 is coupled to a plurality of polisher chambers 160. Each polisher chamber 160 incudes a respective polisher sensor of the one or more polisher sensors 127 and an exhaust of the one or more exhausts 150. The transfer station 105A is disposed in the transfer region 151 of the polishing module 105. The transfer region 151 includes a transfer sensor 124. In some embodiments, the plurality of polisher chambers 160 includes a first polisher chamber 160A, a second polisher chamber 160B, a third polisher chamber 160C, and a fourth polisher chamber 160D. The transfer station 105A includes a robot that transfers substrates from the transfer station 105A to the polisher chambers 160. Each of the polisher chambers 160 includes a corresponding polishing assembly, a transfer aperture, and a service aperture.

For example, the first polisher chamber 160A includes a first polishing assembly 112A, a first transfer aperture 161A, and a first service aperture 171. The second polisher chamber 160B includes a second polishing assembly 112B, a second transfer aperture 161B, and a second service aperture 172. The third polisher chamber 160C includes a third polishing assembly 112C, a third transfer aperture 161C, and a third service aperture 173. The fourth polisher chamber 160D includes a fourth polishing assembly 112D, a fourth transfer aperture 161D, and a fourth service aperture 174.

The transfer station 105A translates a substrate through one or more of the transfer apertures 161A, 161B, 161C, 161D to the one or more polishing assemblies 112. In some embodiments, the transfer apertures 161A, 161B, 161C, 161D are doors that can seal a respective polisher chamber from the other polisher chambers and the transfer region 151 so that service may be performed within polisher chamber through the corresponding service aperture during operation without contaminating the other polisher chambers.

Each polisher chamber of the plurality of polisher chambers 160 includes a corresponding exhaust 150A, 150B, 150C, 150D and a corresponding polisher sensor 127A, 127B, 127C, 127D. The one or more polishing assemblies 112 are each disposed in a corresponding polisher chamber 160A, 160B, 160C, 160D. For example, a first polishing assembly 112A is disposed in the first polisher chamber 160A. The transfer station 105A translates a substrate through a corresponding substrate aperture. For example, the transfer station 105A translates a substrate through a first transfer aperture 161A to dispose the substrate on a first polishing assembly 112A.

As shown in FIG. 1, the cleaner module 106 may be comprised of two cleaning units 106A, 106B disposed in parallel to one another on opposite sides of the second substrate handler 104. The cleaning units 106A, 106B include a plurality of cleaning modules, such as one or more first cleaning modules, one or more second cleaning modules and one or more third cleaning modules, as discussed below.

As can be appreciated from FIG. 1 and as described above, cleaning unit 106B is essentially a mirror-duplicate of the cleaning unit 106A. Accordingly, the description herein and the depiction of cleaning unit 106A in the Figures is to be understood inferentially as also a description and depiction of cleaning unit 106B.

The cleaning units 106A, 106B may be separated by a robot tunnel 104T in which the second substrate handler 104 is positioned. Each cleaning unit 106A, 106B may include a first cleaning module 107, a third substrate handler 108, a brush box cleaner 109, and a third cleaning module 110. In some embodiments, the third cleaning module 110 is referred to herein as a drying module 110. In some embodiments, the brush box cleaner 109 may be provided as one or more brush box cleaners including a first brush box cleaner 109A and a second brush box cleaner 109B. For example, the brush box cleaner 109 may be provided as three brush box cleaners. In some embodiments, the third cleaning module 110 may be provided as a first drying module 110A and a second drying module 110B.

The first cleaning module 107 receives a polished substrate 101 from the second substrate handler 104 through a first door 107A formed in a first side panel of the first cleaning module 107. The first door 107A may be, for example, a slit valve that is configured to isolate an interior region of the first cleaning module 107 from the exterior region of the first cleaning module 107. The substrate 101 is received in a horizontal orientation by the first cleaning module 107 for positioning on a horizontally disposed substrate support surface therein. The first cleaning module 107 then performs a pre-clean process before the substrate 101 is transferred therefrom using the third substrate handler 108.

The polishing system 100 maintains an environment within the system. The environment includes a fluid flow path 120 defined through the factory interface module 102, the cleaner module 106, and the polishing module 105. The fluid flow path 120 begins in the factory interface module 102 and ends at the corresponding exhaust 150A, 150B, 150C, 150D in the polishing module 105. The fluid flow path 120 includes a first fluid flow path 120A, a second fluid flow path 120B, and a third fluid flow path 120C.

In some embodiments, the first fluid flow path 120A is a first sub path of the fluid flow path 120, the second fluid flow path 120B is a second sub path of the fluid flow path 120 parallel to the first sub path, and the third fluid flow path 120C is a third sub path of the fluid flow path 120 parallel to the first sub path and second sub path.

The polishing system 100 also includes a factory interface sensor 121, a first cleaning system sensor 122, a second cleaning system sensor 123, the transfer sensor 124, a tunnel sensor 125, and an ambient sensor 126. The sensors 121, 122, 123, 124, 125, 126, 127A, 127B, 127C, 127D monitor the first fluid flow path 120A, the second fluid flow path 120B, and the third fluid flow path 120C of the fluid flow path 120. The factory interface sensor 121 is disposed within the factory interface module 102. The first cleaning system sensor 122 is disposed within the cleaning unit 106A and the second cleaning system sensor 123 is disposed within the cleaning unit 106B. The transfer sensor 124 is disposed within the polishing module 105. The tunnel sensor 125 is disposed in the robot tunnel 104T. The ambient sensor 126 is disposed on an exterior of the polishing system 100. The first fluid flow path 120A has a first leg 131a, a second leg 133a, and a third leg 135a. The second fluid flow path 120B has a first leg 131b, a second leg 133b, and a third leg 135b. The third fluid flow path 120C has a first leg 131c, a second leg 133c, and a third leg 135c. The sensors 121, 122, 123, 124, 125, 126, 127A, 127B, 127C, 127D detect one or more characteristics of the fluid flow path 120 at each leg 131a, 131b, 133a, 133b, 135a, 135b 131c, 131c, 133c. In some embodiments, a characteristic is pressure and the sensors 121, 122, 123, 124, 125, 126, 127A, 127B, 127C, 127D are pressure sensors that detect the pressure of the fluid as the fluid translates along the first fluid flow path 120A, the second fluid flow path 120B, and the third fluid flow path 120C.

In some embodiments, the characteristic is a pressure differential and the sensors 121, 122, 123, 124, 125, 126, 127A, 127B, 127C, 127D are pressure sensors that detect the pressure of the fluid as the fluid translates along fluid flow path 120. A threshold or boundary condition may be when the pressure differential between two sensors is negative and corresponds to a downstream sensor detecting a greater pressure than an upstream sensor. Up and down stream as defined herein correspond to the factory interface 102 and polishing module 105, where upstream is closer to the inlet 140 of the factory interface 102 and downstream corresponds to the exhausts 150. By detecting the pressures along the flow path, pressure differentials can be determined and pressures can be compared against one another and against the ambient pressure detected by the ambient sensor 126. This pressure comparison allows a decrease in pressure that corresponds to a one direction flow path through the CMP processing system 100. The one direction flow path enables reduced contaminants by enhance removal of contaminants from the fluid to the one or more exhausts 150. The one direction flow path further enables reduced contaminants by moving air from less contaminated modules towards more contaminated modules. For example, from the factory interface module 102 to the polishing module 105.

In some embodiments, the first fluid flow path 120A, the second fluid flow path 120B, and the third fluid flow path 120C converge in the transfer region 151. From the transfer region 151, the fluid flow path 120 translates along a first polisher fluid flow path 138A, a second polisher fluid flow path 138B, a third polisher fluid flow path 138C, a fourth polisher fluid flow path 138D, or any combination thereof. Each polisher fluid flow path 138A, 138B, 138C, 138D is a leg of the fluid flow path 120 from the transfer region 151 to the corresponding exhaust 150A, 150B, 150C, 150D.

In some embodiments, a characteristic is velocity and The sensors 121, 122, 123, 124, 125, 127A, 127B, 127C, 127D are velocity sensors that detect the velocity of the fluid as the fluid translates along the first fluid flow path 120A and the second fluid flow path 120B.

The polishing system 100 includes a flow kit 130. The flow kit 130 includes the sensors 121, 122, 123, 124, 125, 126, 127A, 127B, 127C, 127D, an inlet 140, and the one or more exhausts 150. In some embodiments, the inlet 140 is disposed in the factory interface module 102 and the one or more exhausts 150 are disposed in the polishing module 105. The inlet 140 may include one or more of a controllable damper, a fan unit, a fan filter unit, a modulated air supply unit, and a combination thereof. In some embodiments, each of the one or more exhausts 150 is a controllable damper. The inlet 140 provides a fluid that translates along the first fluid flow path 120A and the second fluid flow path 120B of the fluid flow path 120 to the one or more exhausts 150. In some embodiments, the fluid is a gas. In some embodiments, the fluid is filtered air. In some embodiments, the fluid is nitrogen gas. The inlet 140 and the one or more exhausts 150 are configured to maintain a pressure in the factory interface module 102 that is higher than a pressure in the cleaner module 106. The inlet 140 and the one or more exhausts 150 are further configured to maintain the pressure in the cleaner module 106 that is higher than a pressure in the polishing module 105. In some embodiments, one or both of the inlet 140 and the one or more exhausts 150 are flow devices that can be modulated in response to instructions from a controller 190.

In some embodiments, the flow kit 130 further includes a first flow device 137A and a second flow device 137B disposed in the cleaner module 106. For example, the first flow device 137A is disposed in the first cleaning unit 106A and the second flow device 137B is disposed in the second cleaning unit 106B. In some embodiments, the flow first flow device 137A and the second flow device 137B are similar to the inlet 140 and are able to supply modulated air into the polishing system 100.

In some embodiments, the flow kit 130 also includes the first door 107A and a second door 111. The second door 111 is a sealable aperture disposed between the factory interface module 102 and the cleaner module 106. Each of the cleaning unit 106A and the cleaning unit 106B include the second door 111. The first door 107A and second door 111 of each module enable isolation of a portion of the CMP processing system 100 for a maintenance process when one of the modules is set to a service mode.

In some embodiments, the first flow device 137A and the second flow device 137B are fan units connected to the controller 190. The controller 190 is able to adjust one or more characteristics of the first fluid flow path 120A and the second fluid flow path 120B of the fluid flow path 120 by actuating the fan units. Actuating the fan units includes adjusting a fan speed of the fan unit. For example, the first flow device 137A and the second flow device 137B are fan unit configure to supply more air to the fluid flow path 120 to maintain a higher pressure in the cleaner module 106 than the polishing module 105. In some embodiments, the first flow device 137A and the second flow device 137B receive fluid from the same source as the inlet 140.

The inlet 140 and the one or more exhausts 150 are configured to maintain a pressure in the factory interface module 102 that is higher than a pressure in the cleaner module 106. For example, the pressure in the factory interface module 102 is about 0.005 inches water column or greater and the pressure in the polishing module 105 is less than 0.005 inches water column, for example less than atmospheric pressure. The inlet 140 and the one or more exhausts 150 are further configured to maintain the pressure in the cleaner module 106 that is higher than a pressure in the polishing module 105.

In some embodiments, the inlet 140 and the one or more exhausts 150 are further configured to maintain a velocity of fluid translating through a fluid flow path 120. The velocity of fluid translating through a fluid flow path 120 is about 1 to 1,000 feet per minute.

The CMP processing system 100 may include the controller 190, such as a programmable computer, connected the first substrate handler 103 and second substrate handler 104 to transfer the substrate 101 through the system 100.

The controller 190 includes a programmable central processing unit (CPU) 192, which is operable with a memory 194 (e.g., non-volatile memory) and support circuits 196. The support circuits 196 are conventionally coupled to the CPU 192 and comprise cache, clock circuits, input/output subsystems, power supplies, and the like, and combinations thereof coupled to the various components of the polishing system 100.

In some embodiments, the CPU 192 is one of any form of general purpose computer processor used in an industrial setting, such as a programmable logic controller (PLC), for controlling various monitoring system component and sub-processors. The memory 194, coupled to the CPU 192, is non-transitory and is typically one or more of readily available memory such as random access memory (RAM), read only memory (ROM), floppy disk drive, hard disk, or any other form of digital storage, local or remote.

The memory 194 may be in the form of a computer-readable storage media containing instructions (e.g., non-volatile memory), that, when executed by the CPU 192, facilitates the operation of the polishing system 100. The instructions in the memory 194 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

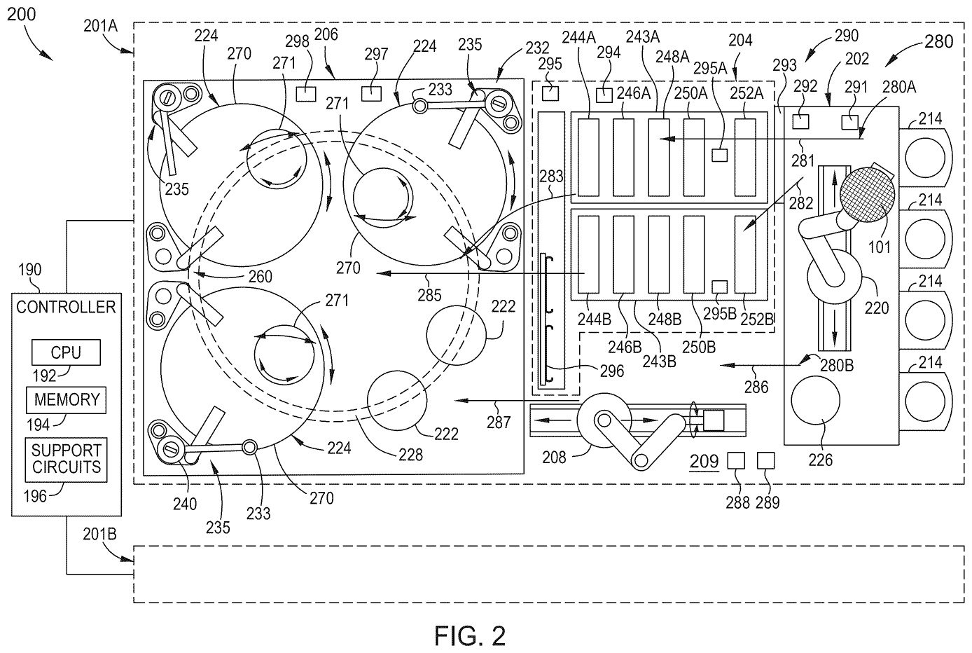

The controller 190 is configured to monitor changes in the system 100 and/or a system 200 (FIG. 2). For example, the controller 190 is in communication with the inlet 140, the one or more exhausts 150, and the sensors 121, 122, 123, 124, 125, 126, 127A, 127B, 127C, 127D. Although illustrated as a single computer, the controller 190 could be a distributed system, e.g., including multiple independently operating processors and memories. The computer architecture is adaptable to various monitoring operations based on programming of the controller 190 to monitor one or more characteristics of the fluid flow path 120.

For example, the controller 190 receives signals from the sensors 121, 122, 123, 124, 125, 126, 127A, 127B, 127C, 127D and transmits signals with the inlet 140, the first flow device 137A, the second flow device 137B, and the one or more exhausts 150 to maintain a positive pressure differential along the fluid flow path 120. In some embodiments, the controller 190 determines if a pressure gradient along the fluid flow path 120 is within a threshold range based on the pressure detected by the sensors 121, 122, 123, 124, 125, 126, 127A, 127B, 127C, 127D. In some embodiments, the controller 190 determines if a pressure change occurs along the first fluid flow path 120A or second fluid flow path 120B is within a threshold range based on the pressure detected by the sensors 121, 122, 123, 124, 125, 126, 127A, 127B, 127C, 127D.

In some embodiments, the controller 190 determines if a velocity of the fluid along the fluid flow path 120 is within a threshold range based on a pressure or velocity detected by the sensors 121, 122, 123, 124, 125, 126, 127A, 127B, 127C, 127D. In some embodiments, the controller 190 determines if a velocity change that occurs along the first fluid flow path 120A or second fluid flow path 120B is within a threshold range based on the pressure or velocity detected by the sensors 121, 122, 123, 124, 125, 126, 127A, 127B, 127C, 127D.

The controller 190 creates an alert if one or more of the pressure gradient, the pressure change, the velocity of the fluid, or the velocity change is outside of the respective threshold. The alert provides notice that an excursion event has occurred. The excursion event is when one or more characteristic is outside of its threshold. The alert may include sending power to an indicator, transmitting an alert instruction, displaying a message, or any combination thereof.

The controller 190 is able to compare the first fluid flow path 120A and the second fluid flow path 120B during similar operations to detect anomalies present in one of the cleaning units 106A, 106B when compared to the other. These differences can be used to detect excursion events and form alerts based on excursion events. The methods of detection, monitoring, and alert generation will be described in more detail below.

In some embodiments, the controller 190 determines an airflow model within the CMP processing system 100 along the fluid flow path 120. The controller 190 generates the airflow model based on the signals from the sensors 121, 122, 123, 124, 125, 127A, 127B, 127C, 127D. For example, the controller 190 generates the airflow model based on the pressure or velocity detected by the sensors 121, 122, 123, 124, 125, 127A, 127B, 127C, 127D. The airflow model includes a model of the first fluid flow path 120A and the second fluid flow path 120B. In some embodiments, the controller 190 determines if a difference that occurs between the first fluid flow path 120A and second fluid flow path 120B is within a threshold range based on the pressure or velocity detected by the sensors 121, 122, 123, 124, 125, 127A, 127B, 127C, 127D.

FIG. 2 is a top plan view of a CMP processing system 200 according to one or more embodiments.

The CMP processing system 200 includes a first module 201A, a second module 201B, and the controller 190. As can be appreciated from FIG. 2 and as described below, the first module 201A and the second module 201B are essentially duplicates. Accordingly, the description herein and the depiction of the first module 201A in FIG. 2 is to be understood inferentially as also a description and depiction the second module 201B. While only two modules are shown, multiple modules are contemplated. For example, three modules, four modules, and five or more modules.

Each of the first module 201A and the second module 201B of the CMP processing system 200 includes a factory interface module 202, a cleaner module 204, and a polishing module 206. One or more substrates 101 are processed within the CMP processing system 200 to polish a surface of the substrate 101.

The first module 201A includes a wet robot 208 to transfer the substrates 101 between the factory interface module 202, the polishing module 206, and the cleaner module 204. The wet robot is disposed in a wet tunnel 209 of the first module 201A. The factory interface module 202 includes a dry robot 220 configured to transfer the substrates 101 between one or more cassettes 214 and one or more transfer platforms 226 of the factory interface module 202. Substrates 101 are loaded into the CMP processing system 200 via the cassettes 214. The dry robot 220 additionally is configured to receive the substrates 101 from the cleaner module 204 and return the clean polished substrates to the substrate storage cassettes 214.

FIG. 2 shows an exemplary polishing module 206 that includes a plurality of polishing stations 224 on which the substrates 101 are polished while being retained in a carrier head 271 (e.g., polishing head). Each polishing station 224 includes a polishing pad 270 having a polishing surface capable of polishing a substrate 101, a conditioning assembly 232, a first fluid delivery arm 235, and a second fluid delivery arm 260. Both of the first fluid delivery arm 235 and the second fluid delivery arm 260 selectively deliver a respective first and second fluid to the polishing pad 270. While the polishing module 206 is shown having three polishing stations 224, the polishing module 206 may have more than three polishing stations 224. The polishing stations 224 are sized to interface with one or more carrier heads 271 to facilitate polishing the substrate 101. The carrier heads 271 are coupled to a carriage (not shown) that is mounted to an overhead track 228 that is shown in phantom in FIG. 2. The overhead track 228 allows the carriage to be selectively positioned around the polishing module 206, which facilitates positioning of the carrier heads 271 selectively over the polishing stations 224 and a load cup 222.

The conditioning assembly 232 includes a pad conditioning assembly 240, which dresses the polishing surface of the polishing pad 270 by removing polishing debris and opening the pores of the polishing pad 270 by use of a pad condition disk 233.

The load cups 222 may serve multiple functions, including washing the carrier head 271, receiving the substrate 101 from the wet robot 208, washing the substrate 101, and loading the substrate 101 into the carrier heads.

The controller 190 is coupled to the first module 201A and the second module 201B. The controller 190 controls aspects of the CMP processing system 200 during a CMP process (e.g., cleaning, drying, polishing process, polishing operation, polishing). The controller 190 is able to compare the two modules during similar operations to detect anomalies present in one module when compared to the other. These differences can be used to detect excursion events and form alerts based on excursion events. For example, the controller 190 is able to compare the pressure in the polishing module 206 and the cleaner module 204. In another example, the controller 190 is able to compare the pressure in the cleaner module 204 of each module 201A, 201B. In another example, the controller 190 is able to compare the pressure in each of the cleaning units 106A, 106B (FIG. 1). The above described comparison examples may be used together to compare units, modules, and systems to detect anomalies in reference to each other or from deviations of pressure outside of predefined thresholds.

The substrate 101 may be polished in one or more of the polishing stations 224. For example, a carrier head 271 may retrieve an unpolished substrate 101 from a load cup 222. The carrier head 271 and substrate 101 chucked thereto are then moved to a first polishing station 224, such as the polishing station 224 in the lower right corner of the polishing module 206 farthest from the cleaner module 204. A CMP polishing operation is performed on the substrate 101 in the first polishing station 224. Once the substrate 101 is polished in the first polishing station 224, then the carrier head 271 moves the substrate 101 to a second polishing station 224 (e.g., the polishing station 224 in the upper left corner of the polishing module 206) for additional CMP polishing. For example, the second polishing station 224 may polish the surface of the substrate 101 to form trench lines of a desired height. In some embodiments, the carrier head 271 and substrate 101 may optionally be transferred from the second polishing station 224 to a third polishing station 224 (e.g., the polishing station 224 in the lower left corner of the polishing module 206) to subject the substrate 101 to additional polishing operations.

After polishing, the wet robot 208 transports the polished substrate 101 from the load cup 222 to the cleaner module 204, where slurry residues and other contaminants that have accumulated on the surface of the substrate 101 during polishing are removed. The cleaner module 204 includes one or more sub-cleaner modules 243. In some embodiments, the sub-cleaner modules 243 include a first cleaner module 243A and a second cleaner module 243B. The first cleaner module 243A includes a first pre-clean module 244A, a first megasonic cleaner module 246A, a first brush box module 248A, a first spray jet module 250A, and a first drying module 252A. The second cleaner module 243B includes a second pre-clean module 244B, a second megasonic cleaner module 246B, a second brush box module 248B, a second spray jet module 250B, and a second drying module 252B. In some embodiments, the sub-cleaner modules 243 are parallel so that multiple substrates can be processed in the cleaner module 204. For example, a first substrate can be processed by the first pre-clean module 244A and a second substrate can simultaneously be processed in the second megasonic cleaner module 246B. The dry robot 220 then removes the substrate 101 from the cleaner module 204. Finally, the dry robot 220 returns the substrate 101 to one of the cassettes 214.

The CMP processing system 200 includes a respective fluid flow path 280 of each module 201A, 201B, and an airflow monitoring kit 290. The airflow monitoring kit 290 includes one or more flow devices disposed along the respective fluid flow path 280 of each module 201A, 201B. The airflow monitoring kit 290 includes one or more of a tunnel sensor 288, an inlet 291, a factory interface (FI) sensor 292, a first door 293, a supply unit 294, a cleaner sensor 295, a second door 296, a polisher sensor 297, and an exhaust 298. The controller 190 is connected to the airflow monitoring kit 290 and is able to monitor the fluid flow path 280 and control the components of the airflow monitoring kit 290. In some embodiments, the cleaner sensor 295 includes a first cleaner sensor 295A disposed in the first cleaner module 243A and a second cleaner sensor 295B disposed in the second cleaner module 243B.

The fluid flow path 280 is a flow path of a fluid from the inlet 291 to the exhaust 298. The sensors 292, 295, 295A, 295B, 288, 297 detect characteristics of the fluid flow path 280. The fluid flow path 280 is the path of the fluid through each module starting at the factory interface module 202 and proceeding to the module 204 and then the polishing module 206. The one direction flow path enables reduced contaminants by enhance removal of contaminants from the fluid to the exhaust 298. The one direction flow path further enables reduced contaminants by moving air from less contaminated modules towards more contaminated modules. In some embodiments, the fluid flow path 280 includes a first fluid flow path 280A and a second fluid flow path 280B. The first fluid flow path 280A starts at the inlet 291, goes through the cleaner module 204, and ends at the exhaust 298. The pressure is greater at the start of the first fluid flow path 280A than at the end. The second fluid flow path 280B starts at the inlet 291, goes through the wet tunnel 209, and ends at the exhaust 298. The pressure is greater at the start of the second fluid flow path 280B than at the end. In some embodiments, the wet tunnel 209 includes a flow device 289 and the tunnel sensor 288. In some embodiments, the flow device 289 is an inlet similar to the inlet 291.

In some embodiments, the first fluid flow path 280A includes a first leg or first sub path 281 from the factory interface module 202 to the first cleaner module 243A and a second leg or second sub path 282 from the factory interface module 202 to the second cleaner module 243B. The first fluid flow path 280A further includes a third leg or third sub path 283 from the first cleaner module 243A to the polishing module 206 and a fourth leg or fourth sub path 285 from the second cleaner module 243B to the polishing module 206.

In some embodiments, the second fluid flow path 280B includes a first leg or first sub path 286 from the factory interface module 202 to the wet tunnel 209 and a second leg or second sub path 287 from the wet tunnel 209 to the polishing module 206.

The inlet 291 is disposed in the factory interface module 202. In some embodiments, the inlet 291 is a motorized damper that controls the amount of fluid allowed into the factory interface module 202. In some embodiments, the inlet 291 is a fan unit, a fan filter unit, a modulatable supply unit, or a combination thereof. The FI sensor 292 is disposed in the factory interface module 202 and detects characteristics of the respective fluid flow path 280 of the respective module 201A, 201B. For example, the FI sensor 292 is a pressure sensor disposed in the factory interface module 202 and the characteristic is a pressure differential between the factory interface module 202 and the first cleaner module 243A. If the pressure differential between the factory interface module 202 and the first cleaner module 243A is positive, then the pressure in the factory interface module 202 is greater than the pressure in the first cleaner module 243A. If the pressure differential between the factory interface module 202 and the first cleaner module 243A is negative, then one or more of the pressure differential, the pressure in the factory interface module 202, or the pressure of the first cleaner module 243A is not within a threshold or is outside of a boundary condition.

The first door 293 is disposed between the factory interface module 202 and the cleaner module 204. The first door 293 enables a pressure seal between the factory interface module 202 and the cleaner module 204.

The supply unit 294 and the cleaner sensor 295 are disposed in cleaner module 204. In some embodiments, the supply unit 294 is a fan unit configured to supply air to the fluid flow path 280.

The second door 296 is disposed between the exemplary polishing module 206 and the cleaner module 204. The second door 296 enables a pressure seal between the polishing module 206 and the cleaner module 204.

The polisher sensor 297 and the exhaust 298 are disposed in the polishing module 206. In some embodiments, the exhaust 298 is an actuatable valve. In some embodiments, the exhaust 298 is a fan unit with a controllable fan speed. In some embodiments, the exhaust 298 of each module 201A, 201B is a shared exhaust between each exhaust 298 of the system 200.

The first module 201A and second module 201B may be referred to as a first tool and second tool. Each airflow monitoring kit 290 of each tool is connected to the controller 190. The controller 190 enables comparison of one or more characteristics of the fluid flow path 280 of the first module 201A to the characteristic of the second module 201B. In some embodiments, the controller 190 is able to determine if the characteristic of a first fluid flow path 280 of the first module 201A is within a threshold during operation of the cleaning system 200 when compared to the characteristic of a second fluid flow path 280 of the second module 201B.

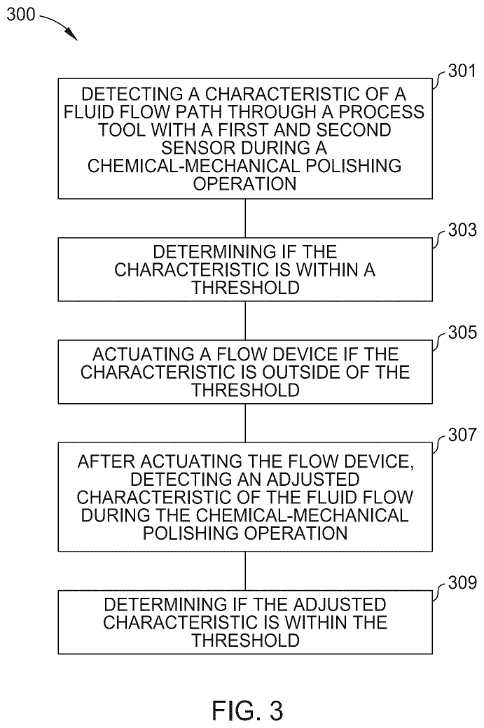

FIG. 3 is a schematic block diagram of a method 300 of maintaining a fluid flow in a CMP system according to one or more embodiments. FIG. 3 will be described in reference to FIG. 1 and FIG. 2.

At operation 301, one or more sensors detect a characteristic of a fluid flow path through a processing system during a chemical-mechanical polishing operation.

In some embodiments, operation 301 occurs in the system 100, the fluid flow path is the fluid flow path 120, and the one or more sensors are one or more of the factory interface sensor 121, the cleaning system sensor 122, or the transfer sensor 124.

In some embodiments, operation 301 occurs in the system 200, the fluid flow path is the fluid flow path 280, and the one or more sensors are one or more of the sensors 292, 295, 295A, 295B, 288, 297.

In some embodiments, the characteristic includes a fluid pressure, a fluid velocity, a differential pressure, or a combination thereof. For example, the fluid is gas within the system and the characteristic is a pressure differential detected by two sensors and determined by the controller 190. In some embodiments, the controller 190 correlates the pressure differential between modules to determine a direction of airflow. In some embodiments, the controller 190 determines changes in pressure during maintenance operations and actuates an inlet to maintain one directional airflow despite disruptions. For example, during a maintenance operation on the chemical mechanical polishing CMP processing system 100, (FIG. 1) fourth transfer aperture 161D may be sealed. When the fourth transfer aperture 161D is sealed, the exhaust 150D is not reducing the pressure of the transfer region 151. To compensate, the controller 190 causes one or more of the inlet 140, the first flow device 137A, the second flow device 137B, or a combination thereof to supply more air to increase the pressure along the fluid flow path 120 upstream of the transfer region 151.

At operation 303, the controller 190 determines if the characteristic is within a threshold. In some embodiments, determining if the characteristic is within the threshold includes forming a ratio between two or more of a factory interface pressure, a cleaner module pressure, and a polishing module pressure. For example, the pressure ratio maybe about 1.001:0.9990:0.90, where the factory interface pressure corresponds to the “1.001,” the cleaner module 106 pressure corresponds to the “0.999,” and the polishing module 105 pressure corresponds to the “0.90.” In some embodiments, the threshold is a positive pressure differential.

In some embodiments, the characteristic is based on pressure and the controller 190 determines if a difference in pressure along the fluid flow path 120 (i.e., a pressure differential detected by at least two of the sensors 121, 122, 124, 125, or 126) is within a pressure threshold. For example, the controller 190 determines if a pressure change along the fluid flow path 120 is within 5% of a target pressure. For example, if the controller 190 determines one of the sensors 292, 295, 295A, 295B, 288, 297 detects a pressure for outside of a predetermined boundary for longer than a 1 second, then the characteristic is outside of the threshold.

In another example, if the controller 190 determines that a ratio between the pressures detected by two of the sensors 292, 295, 295A, 295B, 288, 297 is outside of a predetermined boundary for longer than a second, then the characteristic is outside of the threshold range. In another example, the controller 190 determines if the characteristic is a negative ratio, e.g. a negative pressure differential, where a first pressure detected downstream of a second pressure is greater than the second pressure. If the controller 190 detects a negative pressure differential along the fluid flow path 280, the controller 190 generates an alert that the fluid is no longer in a one directional flow. For example, if the controller 190 determines that the pressure detected by sensors 295A. In some embodiments, the controller 190 determines if a pressure detected along the first fluid flow path 120A is within a threshold of a pressure detected along the second fluid flow path 120B at the corresponding point.

In some embodiments, the controller 190 determines if a pressure detected along the fluid flow path 280 of the first module 201A is within a threshold of a pressure detected along the fluid flow path 280 of the second module 201B at the corresponding point. For example, the controller 190 determines if the pressure detected by one of the sensors 292, 295, 295A, 295B, 288, 297 of the first module 201A is within a threshold range of the pressure detected during a similar CMP operation by the one of the sensors 292, 295, 295A, 295B, 288, 297 of the second module 201B. For example, if the controller 190 determines the pressure detected by polisher sensor 297 of the first module 201A is within 20% of the pressure detected by polisher sensor 297 of the second module 201B when a substrate 101 translates through the respective second door 296, then the pressure detected along the fluid flow path 280 of the first module 201A or the second module 201B is within the threshold.

At operation 305, the controller 190 actuates a flow device if the characteristic is outside of the threshold. In some embodiments, the flow device may be one or more of the first flow device 137A, the second flow device 137B, the inlet 140, the exhausts 150, the corresponding exhaust 150A, 150B, 150C, 150D, the inlet 291, the supply unit 294, or the exhaust 298. In some embodiments, the controller 190 enables a decreasing pressure from the beginning of the fluid flow path to the end of the fluid flow path 120. For example, the factory interface module 102 has a higher pressure than the cleaner module 106, and the cleaner module 106 has a higher pressure than the polishing module 105 so that any contaminants floating in the air are translated toward the one or more exhausts 150. In another example, the controller 190 enables a decreasing pressure along the fluid flow path 280 where the factory interface module 202 has a higher pressure than the cleaner module 204, and the cleaning module 204 has a higher pressure than the polishing module 206.

In some embodiments, the controller 190 actuates one or more of the inlet 291, the supply unit 294, and the exhaust 298 to bring the characteristic within a predetermined threshold. For example, the controller 190 actuates the flow device 137A to maintain the factory interface 102 pressure above the cleaning unit 106A pressure and maintains the cleaning unit 106A pressure above the polishing module 105 pressure.

In some embodiments, the controller 190 actuates the flow device to maintain a characteristic of the first sub path of the fluid flow path through a first module of the system during a maintenance process of a second module of the system, the second module having a second sub path of the fluid flow path disposed therethrough. For example, the controller 190 maintains the characteristic of the first fluid flow path 120A in the first fluid flow path 120A while performing a maintenance process on the cleaning unit 106B and the characteristic of the second fluid flow path 120B is outside of the threshold.

In some embodiments, a maintenance process includes sealing a first aperture, un-sealing the first aperture, and maintaining the characteristic of a first sub path. Maintaining the characteristic of the first sub path may include dynamically actuating the flow device during the sealing and un-sealing of the first aperture. For example, the first aperture may be the first transfer aperture 161A and dynamically actuating the flow device may include actuating one or more of the first flow device 137A, the second flow device 137B, the inlet 140, the exhausts 150, and/or the exhaust, 150B, 150C, 150D in response to the sealing and un-sealing of the first transfer aperture 161A.

In some embodiments, the controller 190 is also able to generate an alert to provide notice to an operator, user, or facility monitoring system that a deviation event has occurred. For example, if the controller 190 determines the characteristic has deviated outside the threshold, the controller 190 is able provide an alert. The alert enables rapid inspection of the system to determine if maintenance is required with minimal loss of through put due to contaminated substrates.

At operation 307, after actuating the flow device, one or more sensors detects an adjusted characteristic of the fluid flow path during the chemical-mechanical polishing operation. In some embodiments, one or more of the sensors 121, 122, 123, 124 detects the adjusted characteristic of the fluid flow path 120 and transmits signals to the controller 190. In some embodiments, one or more of the sensors 292, 295, 295A, 295B, 288, 297 detects the adjusted characteristic of the fluid flow path 280 and transmits signals to the controller 190.

At operation 309, the controller 190 determines if the adjusted characteristic is within the threshold. In some embodiments, the controller 190 is configured to compare the characteristic of the first fluid flow path 120A relative to the characteristic of the second fluid flow path 120B to determine if the adjusted characteristic is within the threshold. For example, the threshold includes the adjusted characteristic being a pressure detected by the cleaning system sensor 122 is within 50% of the pressure detected by the cleaning system sensor 123. The controller 190 is able determine if the characteristic of the first fluid flow path 120A is within a threshold of deviation from the second fluid flow path 120B during similar points in operation of the cleaner module 106. In some embodiments, the controller 190 is actively monitoring the sensors 121, 122, 123, 124 while actuating the flow device of chemical mechanical polishing CMP processing system 100 to determine when the adjusted characteristic is within the threshold. In some embodiments, the controller 190 is actively monitoring the sensors 292, 295, 295A, 295B, 288, 297 while actuating the flow device of the cleaning system 200 to determine when the adjusted characteristic is within the threshold.

In some embodiments, operation 309 further includes maintaining the adjusted characteristic within the within the threshold for the reminder of any processing operations. For example, the controller 190 is configured to maintain the adjusted characteristic within the threshold for continuous CMP operations.

In some embodiments, the controller 190 is configured to operate with a closed loop control where operations 305, 307, and 309 are repeated if, after operation 309, the adjusted characteristic is not within the threshold.

In some embodiments, the controller 190 is configured to compare the characteristic of the fluid flow path 120 over time to determine if the adjusted characteristic is within the threshold. For example, the threshold includes the adjusted characteristic being a pressure change per unit of time detected by one or more of the sensors 121, 122, 123, 124, 125, 126. For example, if the adjusted characteristic is pressure change rate detected by one or more of the sensors 121, 122, 123, 124, 125, 126, then the threshold is when the rate of pressure change is 0.008 inch water column per second or more, then the characteristic is outside of the threshold.

In some embodiments, the method 300 further includes the controller 190 determining if further actuation is required to maintain the characteristic and/or the adjusted characteristic within the threshold. In some embodiments, the controller 190 generates an alert if the adjusted characteristic is outside of the threshold for longer than 1 second or more seconds. For example, if the controller 190 determines further actuation is required and sends instructions to the flow kit 130, but the characteristic remains outside of the threshold, the controller 190 determines a deviation event has occurred and generates an alert.

Benefits of the present disclosure include monitoring of a CMP system during processing, reducing contamination, increasing throughput and efficiency, and reducing chamber downtime.

It is contemplated that one or more aspects disclosed herein may be combined. As an example, one or more aspects, features, components, operations and/or properties of the CMP processing system 100 shown in FIG. 1, the cleaning system 200 shown in FIG. 2, and/or the method 300 of FIG. 3 maybe be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is

1. A processing system comprising:
a factory interface module comprising a substrate receiving aperture;
a cleaner module comprising a drying module;
a polishing module coupled to the cleaner module;
a fluid flow path defined through the factory interface module, the cleaner module and the polishing module;
a first sensor disposed along the fluid flow path;
a second sensor disposed along the fluid flow path; and
a controller in communication with the first sensor and the second sensor, the controller configured to determine if a characteristic of the fluid flow path is outside of a threshold during a chemical-mechanical polishing operation.

2. The processing system of claim 1, wherein the first sensor is disposed in the factory interface module and the second sensor is disposed in the cleaner module or the polishing module and the characteristic is a pressure differential detected by the first sensor and the second sensor.

3. The processing system of claim 1, wherein the fluid flow path begins at the factory interface module and ends at an exhaust disposed in the polishing module.

4. The processing system of claim 1, wherein the first sensor is a first pressure sensor disposed in the factory interface module, the second sensor is a second pressure sensor disposed in the cleaner module, and the processing system further comprises:
a third pressure sensor disposed in the polishing module.

5. The processing system of claim 1, wherein the fluid flow path includes a first fluid flow path and a second fluid flow path, the controller configured to compare the characteristic in the first fluid flow path to the second fluid flow path.

6. A processing system comprising:
a first tool comprising:
a first factory interface module comprising a substrate receiving aperture;
a first cleaner module comprising a drying module;
a first polishing module coupled to the first cleaner module; and
a first fluid flow path defined through the first factory interface module, the first cleaner module, and the first polishing module;
an airflow monitoring kit comprising:
one or more flow devices in communication with the first fluid flow path; and
one or more sensors disposed along the first fluid flow path; and
a controller configured to detect a characteristic of the first fluid flow path with the one or more sensors and actuate one or more of the one or more flow devices if the characteristic is outside of a threshold.

7. The processing system of claim 6, wherein
further comprising a second tool comprising:
a second factory interface module;
a second cleaner module; and
a second polishing module; and
a second fluid flow path defined through the second factory interface module, the second cleaner module, and the second polishing module.

8. The processing system of claim 7, wherein the first tool and the second tool are coupled to a shared exhaust.

9. The processing system of claim 7, wherein the controller is configured to compare the characteristic of the first fluid flow path relative to the characteristic of the second fluid flow path and determine if the characteristic of the first fluid flow path is within the threshold during operation of the processing system.

10. The processing system of claim 6, wherein the first cleaner module comprises:
a first cleaner comprising:
a first sensor of the one or more sensors; and
a first flow device of the one or more flow devices
a second cleaner separated from the first cleaner, the second cleaner comprising:
a second sensor of the one or more sensors; and
a second flow device of the one or more flow devices, wherein
the first fluid flow path comprises:
a first sub path through the first cleaner; and
a second sub path through the second cleaner; and
the controller configured to maintain a pressure in the first cleaner when the second cleaner is in a service mode.

11. The processing system of claim 10, wherein the first flow device is a first fan unit and the second flow device is a second fan unit.

12. A method comprising:
detecting a characteristic of a fluid flow path through a processing system with a first sensor and a second sensor during a chemical-mechanical polishing operation;
determining if the characteristic is within a threshold;
actuating a flow device if the characteristic is outside of the threshold;
after actuating the flow device, detecting an adjusted characteristic of the fluid flow path during the chemical-mechanical polishing operation; and
determining if the adjusted characteristic is within the threshold.

13. The method of claim 12, wherein the characteristic includes a fluid pressure, a fluid velocity, a differential pressure, or a combination thereof.

14. The method of claim 12, further comprising maintaining a decreasing pressure from a beginning of the fluid flow path to an end of the fluid flow path.

15. The method of claim 12, wherein actuating the flow device includes one or more of actuating an inlet, adjusting a fan speed of a fan unit coupled to the processing system, actuating an exhaust, or a combination thereof.

16. The method of claim 12, wherein detecting the characteristic of the fluid flow path comprises:
detecting a factory interface pressure in a factory interface module of the processing system;
detecting a cleaner module pressure in a cleaner module of the processing system; and
detecting a polishing module pressure in a polishing module of the processing system; and
wherein the determining if the characteristic is within the threshold comprises:
forming a ratio between two or more of the factory interface pressure, the cleaner module pressure, and the polishing module pressure.

17. The method of claim 16, further comprising:
maintaining the factory interface pressure above the cleaner module pressure; and
maintaining the cleaner module pressure above the polishing module pressure.

18. The method of claim 12, further comprising maintaining the characteristic of a first sub path of the fluid flow path through a first module of the processing system during a maintenance process of a second module of the processing system, a second sub path of the fluid flow path disposed through the second module.

19. The method of claim 18, wherein the second sub path is parallel to the first sub path.

20. The method of claim 18, wherein the maintenance process comprises:
sealing a first aperture;
un-sealing the first aperture; and
maintaining the characteristic of the first sub path further comprises:
dynamically actuating the flow device during the sealing and the un-sealing of the first aperture.
